(19) United States
(12) Patent Application Publication
(10) Pub. No.: US 2026/0096351 A1
(43) Pub. Date: Apr. 2, 2026

(54) MAGNETIC MEMORY ELEMENT, MAGNETIC MEMORY DEVICE, PHOTONIC SPIN REGISTER, DATA WRITING METHOD, DATA READING METHOD, APPARATUS, AND INFORMATION PROCESSING SYSTEM

(71) Applicant: The University of Tokyo, Tokyo (JP)

(72) Inventors: Satoru Nakatsuji, Tokyo (JP); Tomoya Higo, Tokyo (JP)

(73) Assignee: The University of Tokyo, Tokyo (JP)

(21) Appl. No.: 19/338,086

(22) Filed: Sep. 24, 2025

Related U.S. Application Data
(63) Continuation-in-part of application No. PCT/JP2024/012153, filed on Mar. 27, 2024.

(30) Foreign Application Priority Data
Mar. 28, 2023 (JP) 2023-052021

(51) Int. Cl. H10N 50/10; G11C 11/16; H10N 50/20; H10N 50/85

(52) U.S. Cl. CPC H10N 50/10; G11C 11/161; G11C 11/1673; G11C 11/1675; H10N 50/20; H10N 50/85

(57) ABSTRACT

A magnetic memory element includes an antiferromagnetic layer that is polycrystalline and made of an antiferromagnet exhibiting an anomalous Hall effect. A magnetic order of the antiferromagnet is reversible. The antiferromagnetic layer includes one or more first grains having an average diameter ranging from 20 nm to 200 nm, and a plurality of second grains are present inside at least one of the one or more first grains.

### CROSS-REFERENCE TO RELATED APPLICATIONS

This application is a continuation-in-part application of PCT/JP2024/012153 filed on Mar. 27, 2024, which claims priority to Japanese Patent Application No. 2023-052021 filed on Mar. 28, 2023. The entire contents of the above applications are incorporated herein by reference.

### BACKGROUND OF THE INVENTION

### 1. Field of the Invention

The disclosure relates to a magnetic memory element, a magnetic memory device, a photonic spin register, a data writing method, a data reading method, an apparatus, and an information processing system.

### 2. Description of the Related Art

Ferromagnet-based magnetic random-access memories (MRAMs) have attracted attention as low-power memories for information processing because of their non-volatile nature. In fact, various semiconductor manufacturers employ MRAMs as alternatives to volatile memories such as static random-access memories (SRAMs). Examples of such MRAMs include an STT-MRAM that allows reversal of magnetization of a ferromagnet by a spin-transfer torque (STT) and an SOT-MRAM that allows reversal of magnetization of a ferromagnet by a spin-orbit torque (SOT).

### SUMMARY OF THE INVENTION

Unfortunately, since the existing MRAMs use ferromagnets, reversal speed of magnetization is as slow as about one nanosecond. This makes it difficult to handle a terahertz region (picosecond order) which especially grows increasingly significant in high-speed optical communications. In contrast, antiferromagnets have faster spin response than ferromagnets and are therefore expected to serve as materials for high-speed magnetic memory elements. However, although the potential of antiferromagnets as spintronic materials has been studied in thin films with relatively large size scales, their applicability to actual magnetic memory elements on the nanometer scale has remained uncertain.

The technique of the disclosure has been made in view of the foregoing, and is capable of realizing an antiferromagnet-based magnetic memory element.

A magnetic memory element according to one aspect of the disclosure includes an antiferromagnetic layer that is polycrystalline and made of an antiferromagnet exhibiting an anomalous Hall effect. A magnetic order of the antiferromagnet is reversible. The antiferromagnetic layer includes one or more first grains having an average diameter ranging from 20 nm to 200 nm. A plurality of second grains are present inside at least one of the one or more first grains.

A magnetic memory device according to another aspect of the disclosure includes a plurality of magnetic memory elements. Each of the plurality of magnetic memory elements is defined as the magnetic memory element including the antiferromagnetic layer described above.

A photonic spin register according to another aspect of the disclosure includes the magnetic memory element described above and a photodetector configured to receive a pulse amplitude-modulated optical signal and convert the pulse amplitude-modulated optical signal into a photocurrent. When the photocurrent serving as a write w current flows through a spin Hall layer in an in-plane direction, a spin current is generated in an out-of-plane direction.

A photonic spin register according to another aspect of the disclosure includes the magnetic memory element described above and a light irradiation unit configured to irradiate the antiferromagnetic layer with a pulse amplitude-modulated optical signal. In the antiferromagnetic layer, irradiation with the pulse amplitude-modulated optical signal allows reversal of the magnetic order of the antiferromagnet.

A method of writing data according to another aspect of the disclosure includes reversing the magnetic order of the antiferromagnet in the antiferromagnetic layer according to claim 1 by a spin-orbit torque or a spin-transfer torque. A method of reading data according to another aspect of the disclosure includes measuring a resistance state of the magnetic memory element according t claim 8 obtained by flowing a current through the magnetic memory element in an out-of-plane direction. An apparatus according to another aspect of the disclosure includes the photonic spin register and a unit connected to the photonic spin register inputting/outputting an optical signal from/to the photonic spin register. Also, an information processing system may include at least one information processing apparatus which is provided with the photonic spin register, an input interface receiving an optical signal from the outside, a unit providing at least serial-parallel conversion by the photonic spin register, and an external interface outputting a signal to the outside.

### BRIEF DESCRIPTION OF THE DRAWINGS

FIG. 1A is a perspective view of crystal and spin structures of Mn₃Sn.

FIG. 1B is a plan view of crystal and spin structures of Mn₃Sn.

FIG. 2 is a graph of an X-ray diffraction spectrum of Mn₃Sn.

FIG. 3 is atomic force microscopy (AFM) images a to d of Mn₃Sn samples with thicknesses of 40 nm, 25 nm, 20 nm, and 5 nm, and cross-sectional transmission electron microscope (TEM) images e and f of Mn₃Sn samples with thicknesses of 25 nm and 20 nm.

FIG. 4 is a schematic view of the Hall effect measurements.

FIG. 5A is a graph illustrating magnetic field dependence of Hall resistivity of a Mn₃Sn sample with a thickness of 40 nm.

FIG. 5B is a graph illustrating magnetic field dependence of Hall resistivity of a Mn₃Sn sample with a thickness of 20 nm, on which an Al layer with a thickness of 4 nm is deposited.

FIG. 5C is a graph illustrating magnetic field dependence of normalized Hall resistivities of Mn₃Sn samples with thicknesses of 40 nm and 20 nm, obtained by dividing the Hall resistivities by their respective saturated values.

FIG. 6A is a schematic view of electrically insulating isolated grains of Mn₃Sn.

FIG. 6B is a schematic view of isolated grains of Mn₃Sn connected electrically through a conducting layer.

FIG. 7 is a schematic view of a configuration of a magnetic memory element with a Hall bar structure according to Example 1.

FIG. 8 is a schematic view of a configuration of a magnetic memory element for an SOT-MRAM according to Example 2.

FIG. 9 is a schematic view of a configuration of a magnetic memory element for an STT-MRAM according to Example 3.

FIG. 10 is a schematic view of a configuration of a photonic spin register according to Example 4.

FIG. 11 is a schematic view of a configuration of a photonic spin register according to Example 5.

FIG. 12 is a schematic view of a configuration of a photonic spin register according to Example 6.

FIG. 13 is a functional block diagram illustrating one example of an information processing apparatus according to a fifth embodiment; and

FIG. 14 is a functional block diagram illustrating one example of an information processing system having a plurality of information processing apparatuses of FIG. 13.

### DETAILED DESCRIPTION

Exemplary embodiments of the disclosure will be described below with reference to the drawings. The same reference numerals are used to designate the same or similar elements throughout the drawings. The drawings are schematic, and a relationship between a planar dimension and a thickness and a thickness ratio between members are different from reality. Needless to say, there are portions having different dimensional relationships or ratios between the drawings.

To achieve high-speed non-volatile memories, the embodiments employ antiferromagnets instead of ferromagnets. The reason behind this is that a spin response of antiferromagnets is in the terahertz region (picosecond order) that is two to three orders of magnitude faster than that of ferromagnets, and an interaction between the antiferromagnets is weak, which provides the potential to achieve magnetic devices with higher speed and higher density.

The embodiments are especially directed to antiferromagnets that have an antiferromagnetic order with macroscopically broken time-reversal symmetry and exhibit the anomalous Hall effect. Examples of such antiferromagnets include antiferromagnetic metals containing manganese (Mn), and collinear antiferromagnets. (e.g., RuO₂, Mn₅Si₃, CrSb). Examples of the antiferromagnetic metals containing Mn include Mn₃X (X=Sn, Ge, Ga, Rh, Pt, or Ir), Mn₃XN (X=Ga, Sn, or Ni), and gamma-type Mn alloys having a face-centered cubic (fcc) structure. Examples of the gamma-type Mn alloys include Mn₁₋ₓFeₓ, Mn₁₋ₓRhₓ, and Mn₁₋ₓPdₓ.

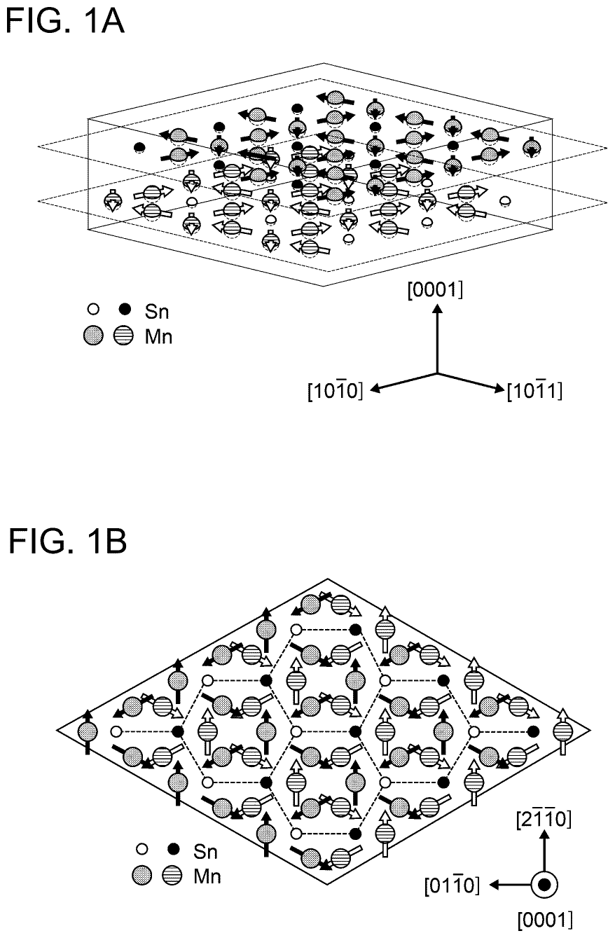

As an example of the antiferromagnets that exhibit the anomalous Hall effect, the properties of Mn₃Sn will be described with reference to FIGS. 1A and 1B.

Mn₃Sn is an antiferromagnet having a crystal structure called kagome lattice that is a triangle-based lattice in which kagome lattice layers are stacked in c-axis [0001] direction as shown in FIGS. 1A and 1B. Mn atoms located at vertices of kagome lattice have a non-collinear chiral spin structure in which magnetic moments (directions of localized spins) are oblique to each other by 120 degrees at temperature of 420 K or below due to geometrical frustration. A unit of six spins consisting of two sets of three spins residing on a kagome lattice bilayer forms a spin order called a cluster magnetic octupole depicted as hexagon. Such a non-collinear magnetic structure can be viewed as ferroic order of the cluster magnetic octupole. This ferroic order breaks the time-reversal symmetry macroscopically.

The cluster magnetic octupole corresponds to a direction of a fictitious magnetic field in a momentum space (100 to 1000 Tesla (T) in a real space) and Weyl points which have a topological electronic structure. Hence, it is possible to manipulate the responses originating from the fictitious magnetic field and Weyl points based on the direction of the cluster magnetic octupole.

The magnetic structure shown in FIGS. 1A and 1B has orthorhombic symmetry, and one of the three magnetic moments of Mn atoms which are triangularly arranged is parallel to an easy axis of magnetization. The other two magnetic moments are canted with respect to the easy axis of magnetization, and thus are believed to induce a weak ferromagnetic moment. Such an antiferromagnet having a canted magnetic moment to exhibit a tiny magnetization is called a canted antiferromagnet.

For Mn₃Sn sample fabrication, a DC magnetron sputtering method can be employed. For example, a Mn₃Sn film is deposited at a high temperature of 500° C. on a thermally oxidized Si substrate from a Mn_{2.7}Sn target in a chamber with a base pressure of <5×10⁻⁷ Pa under the sputtering power of 60 W and Ar pressure of 0.7 Pa. The film is cooled to room temperature immediately after the deposition of the Mn₃Sn film. Thereafter, a capping layer made of aluminum (Al) (with a thickness of 2 nm) is deposited on the Mn₃Sn film in situ at room temperature to prevent oxidation. The method for fabricating Mn₃Sn samples is not limited to the method described above, and alternative fabrication methods may also be employed.

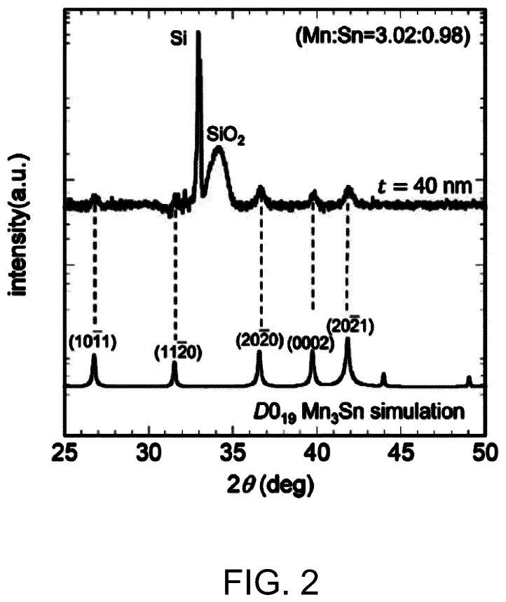

The crystal structures of the Mn₃Sn films can be investigated through X-ray diffraction. The top of FIG. 2 shows an X-ray diffraction spectrum of the Mn₃Sn film (thickness t=40 nm) obtained by a 2θ/ω scan at room temperature when the Mn₃Sn film is deposited on a Si/SiO₂ substrate at 500° C. The bottom of FIG. 2 shows a simulated diffraction pattern of randomly oriented D0₁₉-type Mn₃Sn.

The Mn₃Sn film is found to be a single phase of D0₁₉-type Mn₃Sn because the X-ray diffraction spectrum obtained by the 2θ/ω scan shows the peaks expected from D0₁₉-type Mn₃Sn and the Si/SiO₂ substrate. Moreover, the ratio of the peak intensity is almost consistent with that of the simulation results. These results indicate that the Mn₃Sn film is polycrystalline with a mixture of crystallites with different orientations. The lattice constants are estimated to be a=5.66 Å and c=4.51 Å.

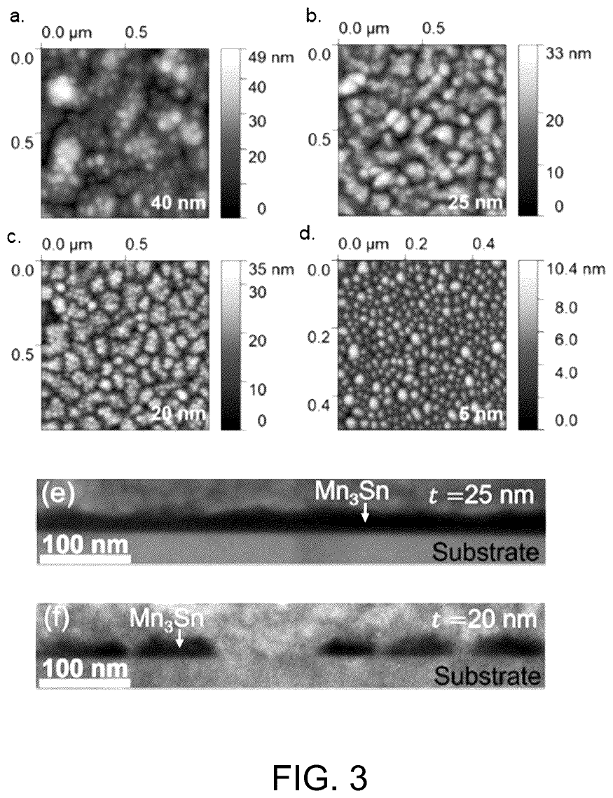

To clarify the structural properties of the Mn₃Sn films, FIG. 3 shows atomic force microscopy (AFM) images a to d of the Mn₃Sn samples with t=40 nm, t=25 nm, t=20 nm, and t=5 nm, and cross-sectional transmission electron microscope (TEM) images e and f of the Mn₃Sn samples with t=25 nm and t=20 nm.

The TEM image e reveals that the t=25 nm sample has a continuous structure, although slight ridges and troughs are observed on the surface. In contrast, the TEM image f reveals that the t=20 nm sample exhibits an isolated island structure with a discontinuous surface. Accordingly, samples with t≥25 nm are electrically conductive due to their continuous structure, while those with t≤20 nm are electrically insulated due to their discontinuous structure.

Moreover, the AFM image c reveals that, in the t=20 nm sample, there are a plurality of grains with a relatively large diameter, hereinafter referred to as “first grains.” It also reveals that a plurality of grains with a relatively small diameter, hereinafter referred to as “second grains,” are present inside each first grain. The average diameter of the first grains in the t=20 nm sample is approximately 100 nm. In contrast, the AFM image d reveals that, in the t=5 nm sample, many first grains with diameters smaller than 20 nm are present, but no second grains are present inside them.

The AFM images c and d, as well as the TEM image f, reveal that the average diameter of the first grains ranges from 20 nm to 200 nm, and that a plurality of second grains are present inside the first grain, the second grains having an average diameter equal to or less than half that of the first grains, and more specifically in the range of 1/20 to 1/2 of that of the first grains.

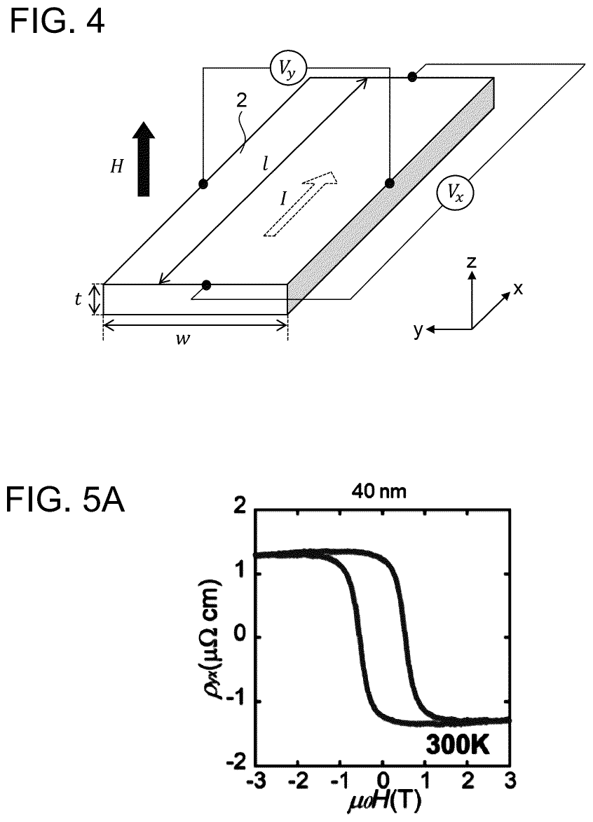

Next, the Hall effect measurements of the antiferromagnet according to the embodiments will be described with reference to FIGS. 4 to 6B.

As shown in FIG. 4, in the Hall effect measurements, when a magnetic field H is applied in the out-of-plane direction (z-direction) of an antiferromagnetic layer 2 and an electric current I is applied in the longitudinal direction (x-direction), the Hall voltage V_{y} generated in the y-direction, which is orthogonal to both the electric current I and the magnetic field H, is measured. Let the length, width, and thickness of the antiferromagnetic layer 2 in the x-, y-, and z-directions be denoted by 1, w, and t, respectively, and the longitudinal voltage in the x-direction be denoted by Vₓ. The longitudinal resistivity ρₓₓ and the Hall resistivity ρ_{yx} are defined as (Vₓ/I)·(wt/l) and (V_{y}/I)·t, respectively.

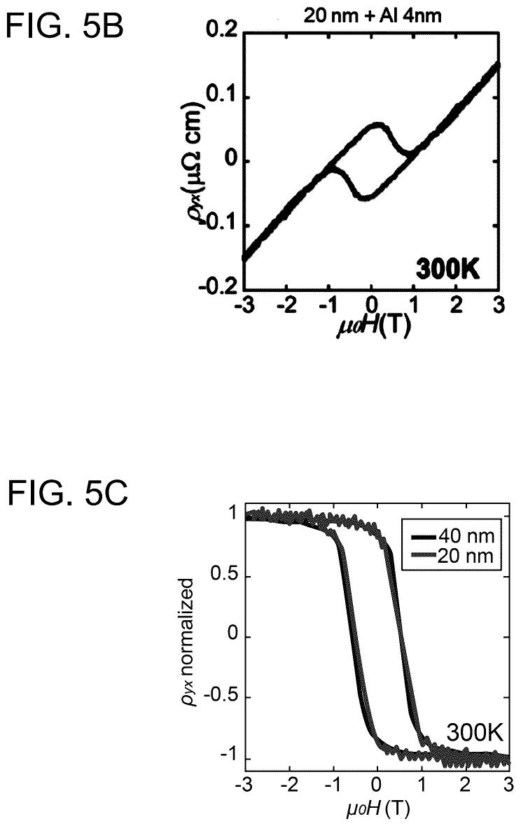

FIG. 5A shows magnetic field dependence of the Hall resistivity ρ_{yx} of a Mn₃Sn sample (antiferromagnetic layer 2) with t=40 nm at 300 K. As shown in FIG. 5A, a clear hysteresis loop is observed. The magnitude of ρ_{yx} at zero magnetic field is approximately 1.3 μΩcm, and the coercivity is approximately 0.6 T. These results confirm that the anomalous Hall effect appears in the Mn₃Sn sample.

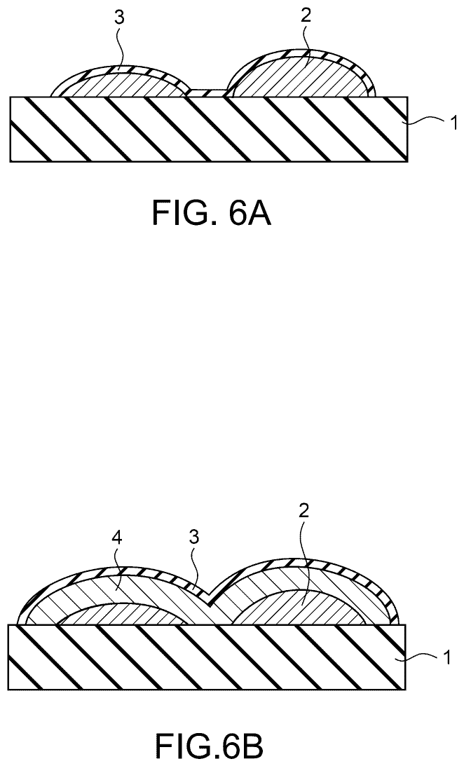

As shown in the TEM image f of FIG. 3, the Mn₃Sn sample with t=20 nm has a discontinuous surface structure. In this case, as shown in FIG. 6A, the antiferromagnetic layer 2 having a plurality of isolated grains made of Mn₃Sn is stacked on a substrate 1, and these isolated grains are covered with an Al capping layer with a thickness of 2 nm. The capping layer is oxidized to form an oxide film 3, resulting in the isolated grains being electrically insulated from one another. In such an insulated state, the Hall effect cannot be measured.

To address this situation, as shown in FIG. 6B, the thickness of the capping layer is increased so that a part of the capping layer remains as a conducting layer 4, thereby electrically connecting the isolated grains via the conducting layer 4. For example, when the thickness of the Al capping layer is 4 nm, 2 nm on the surface side becomes the oxide film 3, while the remaining 2 nm on the side of the antiferromagnetic layer 2 and the substrate 1 serves as the conducting layer 4.

FIG. 5B shows magnetic field dependence of the Hall resistivity ρ_{yx} of a Mn₃Sn sample (antiferromagnetic layer 2) with t=20 nm at 300 K when the sample is covered with an Al capping layer with a thickness of 4 nm. The conducting layer 4 shown in FIG. 6B not only electrically connects the isolated grains, but also causes a large shunting effect. Therefore, the Hall voltage V_{y} of the t=20 nm sample is smaller than that of the continuous film. As shown in FIG. 5B, the magnitude of ρ_{yx} at zero magnetic field is approximately 0.06 μΩcm, which is two orders of magnitude smaller than that of the t=40 nm sample (FIG. 5A). Furthermore, the linear behavior observed in FIG. 5B indicates the occurrence of the ordinary Hall effect in the Al conducting layer 4.

FIG. 5C shows magnetic field dependence of the normalized Hall resistivities of the Mn₃Sn samples with t=40 nm and t=20 nm at 300 K. The normalized Hall resistivities are obtained by first subtracting the component linearly proportional to the magnetic field from the Hall resistivities ρ_{yx}, and then dividing the results by their respective saturated values. By normalizing in this manner, the contribution of the ordinary Hall effect is removed, allowing the two samples to be compared independently of the shunting effect. FIG. 5C reveals that both samples exhibit nearly identical hysteresis loops.

In the Hall effect measurement for the Mn₃Sn sample with t=5 nm, only the ordinary Hall effect is observed. That is, the anomalous Hall effect is not observed in the t=5 nm sample which does not contain second grains, whereas the anomalous Hall effect is observed in the t=20 nm sample in which second grains are present inside a first grain (see FIGS. 5B and 5C). From these results, it can be inferred that the presence of second grains inside a first grain allows the anomalous Hall effect to appear even in grains with very small diameters, ranging from 20 nm to 200 nm.

As described above, the antiferromagnet according to the embodiment has a characteristic nanoscale microstructure and exhibits magnetic effects in a stable manner, making it suitable for application to magnetic memory elements.

According to the disclosure, a magnetic memory element can be realized using an antiferromagnet having a microstructure in which a second grain is present inside a nanoscale first grain.

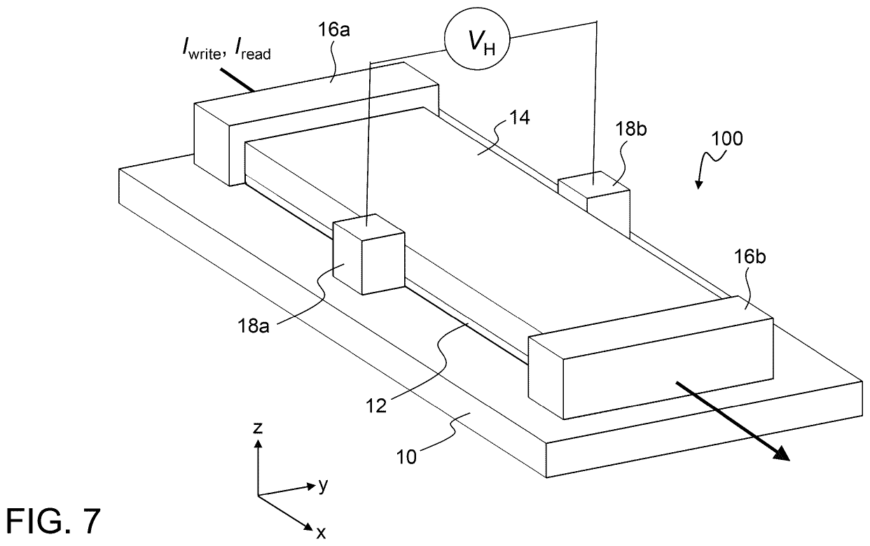

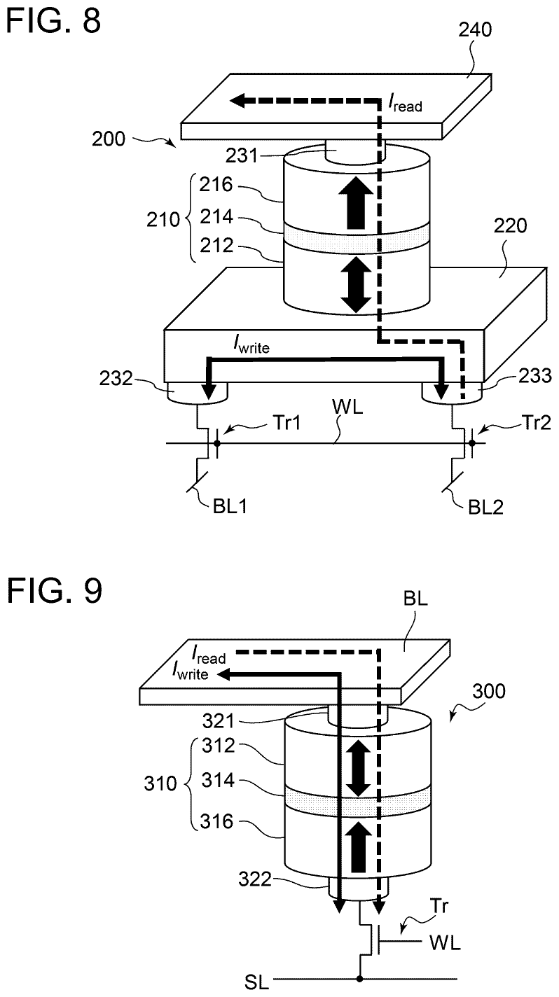

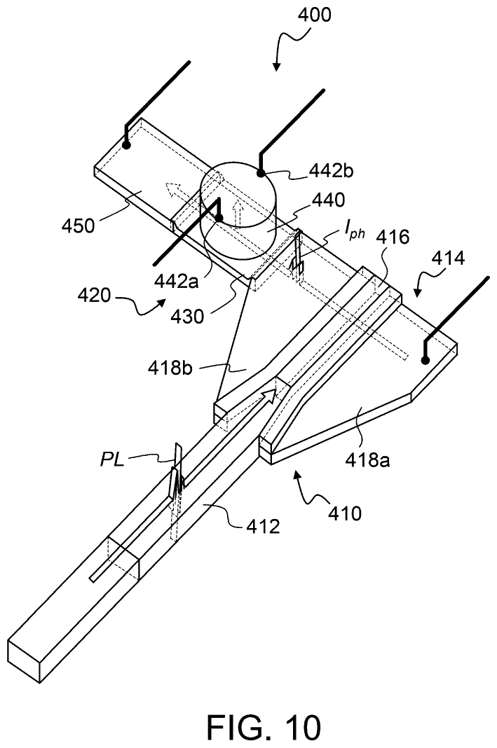

Next, Examples 1 to 6 of the magnetic memory element including the antiferromagnetic layer described above will be described with reference to FIGS. 7 to 12. Example 1 is directed to a magnetic memory element with a Hall bar structure (see FIG. 7), Examples 2 and 3 are directed to magnetic memory elements each having a magnetoresistance element (see FIGS. 8 and 9), and Examples 4 to 6 are directed to photonic spin registers in which data corresponding to an optical signal can be written (see FIGS. 10 to 12). In each of these Examples, one or more first grains correspond to one bit of information.

### Example 1

FIG. 7 shows a configuration of a magnetic memory element 100 according to Example 1. The magnetic memory element 100 includes a substrate 10, a spin Hall layer 12 stacked on the substrate 10, and an antiferromagnetic layer 14 in contact with the spin Hall layer 12.

The substrate 10 is made of an insulator such as MgO and SiO₂. The spin Hall layer 12 is made of a material that exhibits the spin Hall effect (hereinafter referred to as a spin Hall material). Examples of the spin Hall material include a non-magnetic heavy metal such as tantalum (Ta), tungsten (W), and platinum (Pt), and a chalcogenide material such as a topological insulator. The antiferromagnetic layer 14 is a polycrystalline thin film of an antiferromagnet exhibiting the anomalous Hall effect, as described above. The antiferromagnetic layer 14 includes one or more first grains having an average diameter in the range of 20 nm to 200 nm. Inside each first grain, a plurality of second grains are present, having an average diameter not greater than one-half of that of the first grains. In particular, it is more preferable that the average diameter of the second grains falls within a range from one-twentieth to one-half of that of the first grains.

Electrodes 16a and 16b are disposed at both ends in the longitudinal direction (x-direction) of the magnetic memory element 100, and electrodes 18a and 18b are disposed in the transverse direction (y-direction). For example, the electrodes 16a and 16b, and the electrodes 18a and 18b, may be made of Au/Ti.

To write data into the magnetic memory element 100, the write current I_{write} (pulse current) flows through the spin Hall layer 12 between the electrodes 16a and 16b in x-direction. This write current generates a spin current in an out-of-plane direction (z-direction) by the spin Hall effect, and this spin current induces a spin-orbit torque (SOT) to act on the magnetic order (magnetization) of the antiferromagnetic layer 14, thereby allowing reversal of the magnetic order. A weak bias field applied in x-direction affects the magnetic order of the antiferromagnetic layer 14, and determines the rotational direction of the magnetic order.

In this way, the data (“0” or “1”) can be written into the antiferromagnetic layer 14. The orientation of the magnetic order of the antiferromagnetic layer 14 can be controlled depending on the direction of the write current I_{write}. For example, the write current I_{write} flowing in +x-direction reverses the magnetic order from +z-direction (“1”) to −z-direction (“0”), and the write current I_{write} flowing in −x-direction reverses the magnetic order from −z-direction (“0”) to +z-direction (“1”).

To read out the data stored in the antiferromagnetic layer 14, the read current I_{read} (direct current) flows through the antiferromagnetic layer 14 between the electrodes 16a and 16b in x-direction. This leads to detection of the Hall voltage V_{H} between the electrodes 18a and 18b by the anomalous Hall effect. The sign of the Hall voltage V_{H} is determined depending on the z-component of the magnetic order of the antiferromagnetic layer 14. For example, +z-direction and −z-direction of the magnetic order of the antiferromagnetic layer 14 correspond to “1” and “0,” respectively.

Instead of the magnetic memory element 100 shown in FIG. 7, a configuration in which the spin Hall layer 12 is stacked on the antiferromagnetic layer 14 (substrate/antiferromagnetic layer/spin Hall layer) may be employed. Alternatively, the antiferromagnetic layer 14 may be vertically sandwiched between two spin Hall layers made of spin Hall materials having spin Hall angles with opposite signs.

### Example 2

FIG. 8 shows a configuration of a magnetic memory element 200 for an SOT-MRAM according to Example 2. The magnetic memory element 200 includes a magnetoresistance element 210, a spin Hall layer 220, a first terminal 231, a second terminal 232, a third terminal 233, and transistors Tr1 and Tr2.

The spin Hall layer 220 is made of a spin Hall material, similarity to the spin Hall layer 12 shown in FIG. 7. The magnetoresistance element 210 includes a free layer 212 serving as an antiferromagnetic layer which is in contact with the spin Hall layer 220 and whose magnetic order (magnetization) can be reversed, a non-magnetic layer 214 stacked on the free layer 212, and a reference layer 216 which is stacked on the non-magnetic layer 214 and whose magnetic order is fixed in either the in-plane or out-of-plane direction. FIG. 8 illustrates a case where the magnetic order of the free layer 212 and that of the reference layer 216 are oriented in the out-of-plane direction.

The free layer 212 is made of an antiferromagnet that exhibits the anomalous Hall effect, similarity to the antiferromagnetic layer 14 shown in FIG. 7 described above. The non-magnetic layer 214 is made of an insulator (e.g., MgO, AlOₓ, or MgAl₂O₄). The reference layer 216 is made of a ferromagnet (e.g., CoFeB). The reference layer 216 may be made of the same antiferromagnet as the free layer 212. In this case, the antiferromagnet. of the reference layer 216 has a higher coercivity than that of the free layer 212. The magnetoresistance element 210 serves as a magnetic tunnel junction (MTJ) element.

One bit of data “0” or “1” is assigned to the magnetoresistance element 210 depending on its resistance state. For example, when both the free layer 212 and the reference layer 216 are made of Mn₃Sn, the magnetoresistance element 210 is in a low-resistance state when the magnetic orders of the cluster magnetic octupoles in the reference layer 216 and the free layer 212 are aligned in the same direction (parallel state), and in a high-resistance state when the magnetic orders are aligned in opposite directions (anti-parallel state). For instance, the parallel state may be assigned as data “0”,and the anti-parallel state as data “1”. It should be noted, however, that experimentally, the magnetoresistance element 210 may exhibit a high-resistance state in the parallel state and a low-resistance state in the anti-parallel state.

The first terminal 231, the second terminal 232, and the third terminal 233 are made of a metal. The first terminal 231 is connected to the reference layer 216, the second terminal 232 is connected to one end portion of the spin Hall layer 220, and the third terminal 233 is connected to the other end portion of the spin Hall layer 220. The first terminal 231 is connected to a ground line 240. The ground line 240 is set to a ground voltage. The ground line 240 may be set to a reference voltage other than the ground voltage.

Each of the transistors Tr1 and Tr2 is, for example, an N-channel metal oxide semiconductor (NMOS) transistor. The second terminal 232 is connected to a drain of the transistor Tr1, and the third terminal 233 is connected to a drain of the transistor Tr2. Gates of the transistors Tr1 and Tr2 are connected to a word line WL. Sources of the transistors Tr1 and Tr2 are connected to a first bit line BL1 and a second bit line BL2, respectively.

It is assumed that the magnetic order of the free layer 212 and that of the reference layer 216 are oriented in the out-of-plane direction as shown in FIG. 8. To write data into the magnetoresistance element 210, a weak bias field is applied in a direction of a write current I_{write}, the word line WL is set to high level to turn on the transistors Tr1 and Tr2, one of the first bit line BL1 and the second bit line BL2 is set to high level, and the other bit line is set to low level. With these settings, the write current I_{write} flows through the spin Hall layer 220 in the in-plane direction between the first bit line BL1 and the second bit line BL2 to generate a spin current in the out-of-plane direction. This induces an SOT, enabling reversal of the magnetic order of the free layer 212 and allowing data to be written. Data to be written can be changed depending on the direction of the write current I_{write}.

To read out data stored in the magnetoresistance element 210, the word line WL is set to high level to turn on the transistors Tr1 and Tr2, one of the bit lines (second bit line BL2) is set to high level, and the other bit line (first bit line BL1) is set to an open state. With these settings, a read current I_{read} flows from the second bit line BL2 in high level into the ground line 240 through the third terminal 233, the spin Hall layer 220, the free layer 212, the non-magnetic layer 214, the reference layer 216, and the first terminal 231. By measuring the magnitude of the read current I_{read} based on the magnetoresistance effect, the resistance state of the magnetoresistance element 210—that is, the stored data can be determined.

### Example 3

FIG. 9 shows a configuration of a magnetic memory element 300 for an STT-MRAM according to Example 3. The magnetic memory element 300 includes a magnetoresistance element 310, a first terminal 321, a second terminal 322, and a transistor Tr.

The magnetoresistance element 310 includes a reference layer 316 whose magnetic order is fixed in either the in-plane or out-of-plane direction, a non-magnetic layer 314 stacked on the reference layer 316, and a free layer 312 stacked on the non-magnetic layer 314, the free layer 312 being an antiferromagnetic layer whose magnetic order can be reversed. The free layer 312, the non-magnetic layer 314, and the reference layer 316 are each made of the same materials as the free layer 212, the non-magnetic layer 214, and the reference layer 216 shown in FIG. 8, respectively. FIG. 9 illustrates a case where the magnetic order of the free layer 312 and that of the reference layer 316 are oriented in the out-of-plane direction. As with the magnetoresistance element 210 shown in FIG. 8, one bit of data “0” or “1” is allocated to the magnetoresistance element 310 according to its resistance state.

The first terminal 321 and the second terminal 322 are made of a metal. The free layer 312 is connected to the first terminal 321, and the reference layer 316 is connected to the second terminal 322. The first terminal 321 is connected to a bit line BL, and the second terminal 322 is connected to a transistor Tr.

The transistor Tr is, for example, an NMOS transistor. The drain of the transistor Tr is connected to the second terminal 322, the source is connected to a source line SL, and the gate is connected to a word line WL.

To write data into the magnetoresistance element 310, the word line WL is set to a high level to turn on the transistor Tr, and a write current I_{write} is applied in the out-of-plane direction between the bit line BL and the source line SL. This induces a spin-transfer torque, allowing reversal of the magnetic order of the free layer 312, thereby enabling data to be written. The data to be written can be changed depending on the direction of the write current I_{write}.

To read out data stored in the magnetoresistance element 310, the word line WL is set to a high level to turn on the transistor Tr, and a read current I_{read} is applied between the bit line BL and the source line SL. By measuring the magnitude of the read current I_{read} based on the magnetoresistance effect, the resistance state of the magnetoresistance element 310—that is, the stored data—can be determined.

In Example 2 (FIG. 8) and Example 3 (FIG. 9), examples are shown in which the magnetoresistance elements 210 and 310 are MTJ elements, but they may also function as giant magnetoresistance (GMR) elements. In this case, the non-magnetic layers 214 and 314 are made of a non-magnetic metal (conductor).

In Example 2 (FIG. 8), a structure in which an ultrathin ferromagnetic layer (e.g., CoFeB) of 1 nm or less is stacked on the antiferromagnetic layer (antiferromagnetic layer/ferromagnetic layer) may be used as the free layer 212, and a magnetoresistance element having an antiferromagnetic layer/ferromagnetic layer/non-magnetic layer/reference layer structure may be employed. By inverting this stacking structure, a magnetoresistance element having a reference layer/non-magnetic layer/ferromagnetic layer/antiferromagnetic layer structure may be employed in Example 3 (FIG. 9). In this manner, when the antiferromagnetic layer and the ultrathin ferromagnetic layer are magnetically coupled, high-speed control comparable to that of an antiferromagnet can be achieved, and the spin polarization of the ferromagnet can also be utilized, making high-speed memory performance achievable.

### Example 4

FIG. 10 shows a configuration of a photonic spin register 400 according to Example 4. The photonic spin register 400 includes a light receiver 410 and a magnetic memory element 420.

The magnetic memory element 420 includes a spin Hall layer 430 and an antiferromagnetic layer 440 which is in contact with the spin Hall layer 430 and whose magnetic order (magnetization) can be reversed. The spin Hall layer 430 is made of a spin Hall material as in the spin Hall layer 12 shown in FIG. 7. The antiferromagnetic layer 440 is made of an antiferromagnet exhibiting the anomalous Hall effect as in the antiferromagnetic layer 14 shown in FIG. 7.

The light receiver 410 includes an optical wavequide 412 disposed on a substrate, and a photodetector 414 connected to the optical wavequide 412 on the substrate. The photodetector 414 includes a photoelectric conversion element 416, and first and second metal films 418a and 418b between which the photoelectric conversion element 416 is sandwiched, thereby constituting a plasmon waveguide.

The photoelectric conversion element 416 is made of a dielectric material (semiconductor or insulator) and is continuously connected to the optical waveguide 412. The width of the photoelectric conversion element 416 is narrower than that of the optical wavequide 412. The optical wavequide 412 has a tapered shape at its connection to the photoelectric conversion element 416, such that its width decreases toward the photoelectric conversion element 416. A narrower width of the photoelectric conversion element 416 increases the light confinement effect, enabling light to be focused below the diffraction limit, and thereby enhancing the interaction between the photoelectric conversion element 416 and the optical electric field.

The first and second metal films 418a and 418b are made of a metal such as Au or Ag. The second metal film 418b is connected to one end of the spin Hall layer 430. The first metal film 418a also functions as an electrode to which a bias voltage is applied. An electrode 450 is connected to the other end of the spin Hall layer 430, and the electrode 450 is grounded.

Next, an operation of writing data corresponding to an optical signal PL into the magnetic memory element 420 will be described. When a pulse amplitude-modulated optical signal PL is serially input into the photoelectric conversion element 416 via the optical waveguide 412, the optical signal PL propagates in the form of a surface plasmon polariton at the interface between the photoelectric conversion element 416 and the first and second metal films 418a and 418b, generating a strong electric field in the surrounding region. At this time, when the bias voltage is applied, a photocurrent Iₚₕ, which is a pulsed current, flows from the photodetector 414 through the spin Hall layer 430 and into the electrode 450.

When the photocurrent Iₚₕ, serving as a write current, flows in an in-plane direction through the spin Hall layer 430, a spin current is generated in the out-of-plane direction within the spin Hall layer 430. This spin current induces an SOT acting on the magnetic order of the antiferromagnetic layer 440, thereby allowing the magnetic order to be reversed. In this manner, data corresponding to the optical signal PL can be written into the antiferromagnetic layer 440. Since the photocurrent Iₚₕ is a pulsed current based on the optical signal PL, the magnetic order is reversed within a pulse width duration in which an electric current with a current density exceeding a predetermined threshold flows. Outside of this pulse width duration, no reversal of magnetic order occurs.

To read out data stored in the antiferromagnetic layer 440, a read current (direct current) in the same direction as the photocurrent Iₚₕ is applied to the antiferromagnetic layer 440. As a result, due to the anomalous Hall effect, a Hall voltage is generated in a direction orthogonal to the read current, and the Hall voltage is detected between terminals 442a and 442b of the antiferromagnetic layer 440.

As described above, the photonic spin register 400 enables the magnetic order of the antiferromagnetic layer 440 to be reversed by the photocurrent Iₚₕ from the photodetector 414, thereby realizing a high-speed photoelectric interface utilizing spintronics.

### Example 5

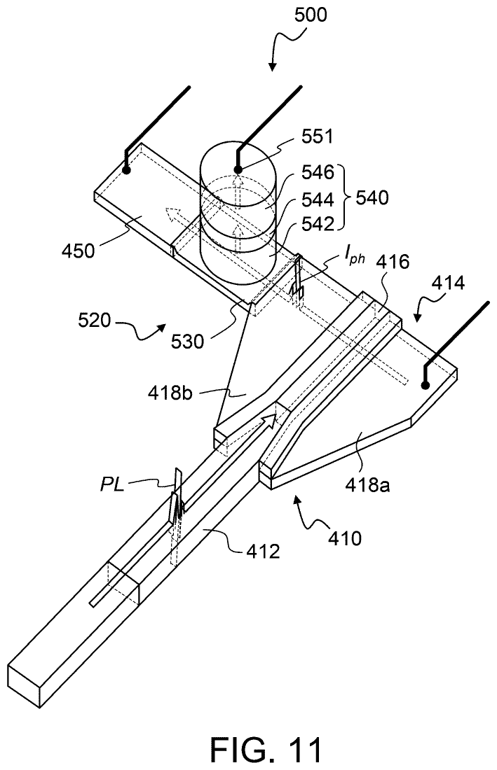

FIG. 11 shows a configuration of a photonic spin register 500 according to Example 5. The photonic spin register 500 includes a light receiver 410 and a magnetic memory element 520. The photonic spin register 500 is configured substantially the same as the photonic spin register 400 shown in FIG. 10, except that the magnetic memory element 420 is substituted with the magnetic memory element 520.

The magnetic memory element 520 includes a spin Hall layer 530 and a magnetoresistance element 540 stacked on the spin Hall layer 530.

The spin Hall layer 530 is made of a spin Hall material as in the spin Hall layer 12 shown in FIG. 7. One end of the spin Hall layer 530 is connected to the second metal film 418b of the photodetector 414, and the other end is connected to the electrode 450.

The magnetoresistance element 540 includes a free layer 542 which is in contact with the spin Hall layer 530 and is an antiferromagnetic layer whose magnetic order (magnetization) can be reversed, a non-magnetic layer 544 stacked on the free layer 542, and a reference layer 546 which is stacked on the non-magnetic layer 544 and whose magnetic order is fixed in either the in-plane or out-of-plane direction. The free layer 542, the non-magnetic layer 544, and the reference layer 546 are each made of the same materials as the free layer 212, the non-magnetic layer 214, and the reference layer 216 shown in FIG. 8, respectively. The reference layer 546 is connected to a terminal 551.

In writing data corresponding to a pulse amplitude-modulated optical signal PL into the magnetic memory element 520, when a photocurrent Iₚₕ corresponding to the optical signal PL flows in the in-plane direction through the spin Hall layer 530, a spin current is generated in the out-of-plane direction. This spin current induces an SOT acting on the magnetic order of the free layer 542, thereby allowing the magnetic order to be reversed. In this manner, data corresponding to the optical signal PL can be written into the magnetoresistance element 540.

To read out data stored in the magnetoresistance element 540, a read current is applied in the out-of-plane direction from the spin Hall layer 530 side toward the magnetoresistance element 540. By measuring the magnitude of the read current via the terminal 551, the resistance state of the magnetoresistance element 540—that is, the stored data-can be determined.

As described above, the photonic spin register 500 enables the magnetic order of the free layer 542 to be reversed by the photocurrent Iₚₕ from the photodetector 414, thereby realizing a high-speed photoelectric interface utilizing spintronics.

### Example 6

Example 6 is directed to a photonic spin register utilizing all-optical magnetization switching (AOS) in which an antiferromagnetic layer is irradiated with an optical signal to reverse a magnetic order (magnetization).

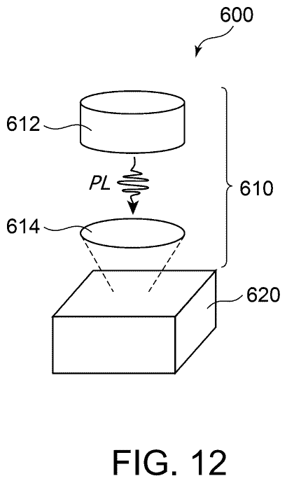

FIG. 12 shows a configuration of a photonic spin register 600 according to Example 6. The photonic spin register 600 includes a light irradiation unit 610 and an antiferromagnetic layer 620 serving as a magnetic memory element.

The antiferromagnetic layer 620 is made of an antiferromagnet exhibiting the anomalous Hall effect as in the antiferromagnetic layer 14 shown in FIG. 7.

The light irradiation unit 610 includes a light emission unit 612 and a lens 614. The light emission unit 612 emits an optical signal PL which is a pulse amplitude-modulated ultrashort pulsed light. The optical signal PL emitted from the light emission unit 612 is focused into the antiferromagnetic layer 620 by the lens 614. Since the optical signal PL is a pulsed light, reversal of the magnetic order of the antiferromagnetic layer 620 occurs when the antiferromagnetic layer 620 is irradiated with light with an intensity equal to or greater than a threshold, and the magnetic order reversal does not occur when the antiferromagnetic layer 620 is irradiated with light with an intensity less than the threshold. In this manner, data corresponding to the optical signal PL can be written into the antiferromagnetic layer 620. Data stored in the antiferromagnetic layer 620 can be read out using, for example, the anomalous Hall effect, as in Examples 1 and 4 (FIGS. 7 and 10).

Unlike Examples 4 and 5 (FIGS. 10 and 11), the photonic spin register 600 does not require a photodetector, that is, it is not necessary to convert the optical signal PL into a photocurrent. Accordingly, the orientation of the magnetic order of the antiferromagnetic layer 620 can be directly controlled by light. Therefore, power consumption due to the photocurrent can be completely suppressed.

In Example 1 (FIG. 7), a magnetic memory device including a plurality of magnetic memory elements 100 may be configured. Furthermore, in Example 2 (FIG. 8), a magnetic memory device including a plurality of magnetic memory elements 200 arranged in a matrix may be configured. In the same manner, in Example 3 (FIG. 9), a magnetic memory device including a plurality of magnetic memory elements 300 arranged in a matrix may be configured. In addition, a computer system or an information processing system including the magnetic memory elements of Examples 1 to 3 or the photonic spin registers of Examples 4 to 6 may be configured.

In Examples 1 and 2 (FIGS. 7 and 8) and Examples 4 and 5 (FIGS. 10 and 11), the spin Hall layer is in contact with the antiferromagnetic layer (free layer), and an SOT causes the magnetic order of the antiferromagnetic layer to be reversed. However, even in a configuration without the spin Hall layer, it is expected that the magnetic order of the antiferromagnetic layer can also be reversed in a single-layer structure.

For example, in addition to the on-chip devices shown in FIGS. 10 and 11, the photonic spin registers of the above-described embodiments are available for various applications. For instance, an information-processing device or a magnetic memory which requires a photoelectric conversion or an electro-optic conversion may include such a photonic spin register.

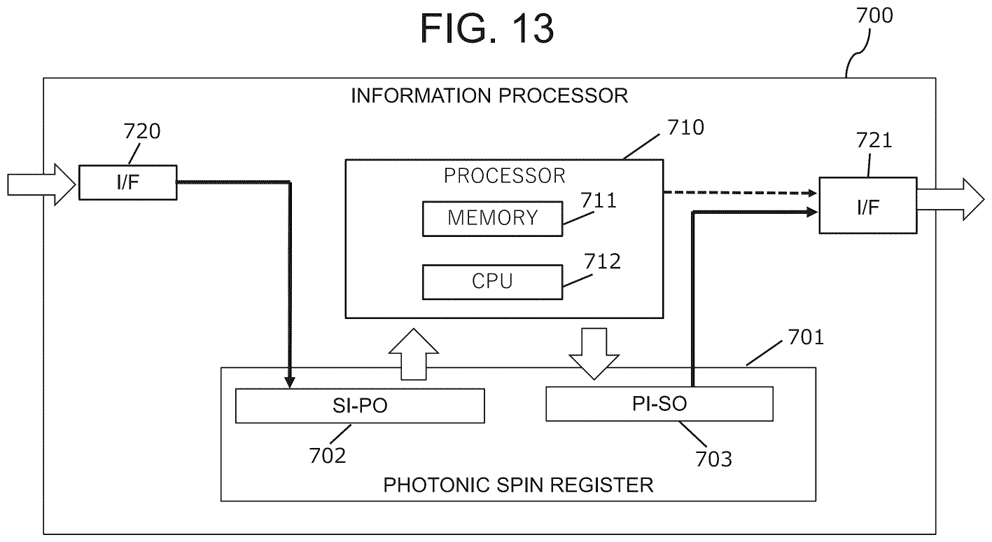

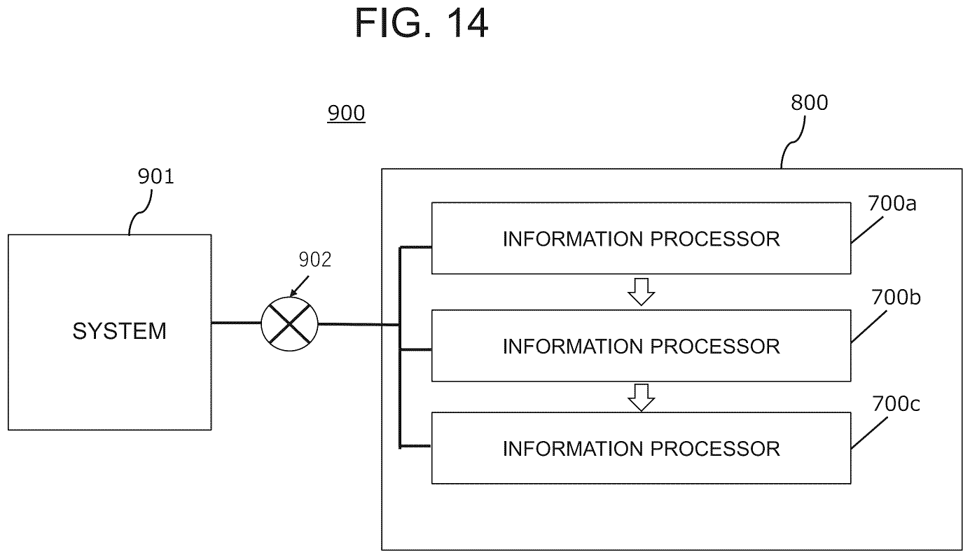

Next, another embodiment of the present invention will be described with reference to FIGS. 13 and 14. The embodiment is directed to an information processing apparatus, and an information processing system including the photonic spin register.

FIG. 13 is a functional block diagram showing an example of an information processing apparatus according to an embodiment of the disclosure. The information processing apparatus 700 includes an input interface 720 that receives an optical signal from the outside, a unit 701 of the photonic spin register having a serial/parallel converter 702 (SI-IPO) that is a receiver and a parallel-serial converter 703 (PI-SO) that is a transmitter, a processing unit 710 having at least a memory 711 and a CPU 712, and an output interface 721 that transmits signals to the outside. A serial optical input signal from the outside passes through the input interface 720 and is converted into a parallel electric signal by the serial-to-parallel converter 702, converted into a desired signal (data) by the processing unit 710, processed by the parallel-serial converter 703 that converts into a serial optical signal, and the optical signal is output to the outside through the output interface 721. If required, a photoelectric conversion unit may be provided in the output interface 721 to output an electric signal, or a parallel-to-serial conversion unit may be provided in the output interface 721 so that the parallel electric signal is directly transferred from the processing unit 710 to the output interface 721 as a serial electric signal and a desired output electrical signal may be output. If desired, interfaces 720 and 721 may be terminals only.

FIG. 14 is a functional block diagram showing an example of an information processing system having a plurality of information processing apparatuses of FIG. 13. The information processing system 900 includes an external system 901, a network 902, and a device 800 housing a plurality of information processing devices 700a to 700c having the same structure as in FIG. 13. Optical signals from the information processing device 700a that receives an optical signal from a device (not shown) inside the device 800 or from the network 902 are output to 700b and 700c, and the information processing results are output to the system 901 via the network 902 as optical signals or electrical signals. Further, the information processing apparatuses 700a to 700c may independently output their respective output signals directly to the system 901, or the signals from the system 901 may be input to the information processing apparatuses 700a to 700c, respectively. Although the number of information processing apparatuses 700a to 700c is three, the number is not limited as long as it is one or more. By using the desired system 901, the information processing system 900 may provide large-scale information system such as a data center or a server, enabling high-speed information processing.

In the above embodiments, when the shift current is always applied, a constant current or a pulse current that is the same as the transmission speed may be applied, or a configuration may be adopted in which the shift current is supplied or cut off at the timing of reading each shift register.

The disclosure is not limited to the above-described embodiments, and various modifications can be made without departing from the scope of the disclosure.

1. A magnetic memory element, comprising:
an antiferromagnetic layer that is polycrystalline and made of an antiferromagnet exhibiting an anomalous Hall effect, wherein
a magnetic order of the antiferromagnet is reversible,
the antiferromagnetic layer includes one or more first grains having an average diameter ranging from 20 nm to 200 nm, and
a plurality of second grains are present inside at least one of the one or more first grains.

2. The magnetic memory element according to claim 1, wherein
an average diameter of the plurality of second grains is equal to or less than one-half of that of the one or more first grains.

3. The magnetic memory element according to claim 2, wherein
the average diameter of the plurality of second grains ranges from one-twentieth to one-half of that of the one or more first grains.

4. The magnetic memory element according to claim 1, wherein
the antiferromagnet has a spin structure with macroscopically broken time-reversal-symmetry.

5. The magnetic memory element according to claim 1, wherein
the antiferromagnet is a canted antiferromagnet.

6. The magnetic memory element according to claim 1, wherein
the antiferromagnet has a spin order of a cluster magnetic octupole.

7. The magnetic memory element according to claim 1, comprising:
a spin Hall layer that is in contact with the antiferromagnetic layer and made of a material exhibiting a spin Hall effect, wherein
when a write current flows through the spin Hall layer in an in-plane direction, a spin current is generated in an out-of-plane direction, and
in the antiferromagnetic layer, the spin current induces a spin-orbit torque to act on the magnetic order of the antiferromagnet, thereby allowing reversal of the magnetic order.

8. The magnetic memory element according to claim 7, comprising:
a reference layer made of a magnetic material whose magnetic order is fixed; and
a non-magnetic layer provided between the antiferromagnetic layer serving as a free layer and the reference layer.

9. The magnetic memory element according to claim 1, comprising:
a reference layer made of a magnetic material whose magnetic order is fixed;
a free layer serving as the antiferromagnetic layer, wherein when a write current flows in an out-of-plane direction, a spin-transfer torque is induced, thereby allowing reversal of the magnetic order of the antiferromagnet; and
a non-magnetic layer provided between the free layer and the reference layer.

10. A magnetic memory device comprising a plurality of magnetic memory elements, wherein
each of the plurality of magnetic memory elements is defined as the magnetic memory element according to claim 7.

11. A magnetic memory device comprising a plurality of magnetic memory elements, wherein
each of the plurality of magnetic memory elements is defined as the magnetic memory element according to claim 8.

12. A magnetic memory device comprising a plurality of magnetic memory elements, wherein
each of the plurality of magnetic memory elements is defined as the magnetic memory element according to claim 9.

13. A photonic spin register, comprising:
the magnetic memory element according to claim 7; and
a photodetector configured to receive a pulse amplitude-modulated optical signal and convert the pulse amplitude-modulated optical signal into a photocurrent, wherein
when the photocurrent serving as the write current flows through the spin Hall layer in the in-plane direction, the spin current is generated in the out-of-plane direction.

14. A photonic spin register, comprising:
the magnetic memory element according to claim 8; and
a photodetector configured to receive a pulse amplitude-modulated optical signal and convert the pulse amplitude-modulated optical signal into a photocurrent, wherein
when the photocurrent serving as the write current flows through the spin Hall layer in the in-plane direction, the spin current is generated in the out-of-plane direction.

15. A method of data writing, comprising:
reversing the magnetic order of the antiferromagnet in the antiferromagnetic layer according to claim 1 by a spin-orbit torque or a spin-transfer torque.

16. A method of reading data, comprising:
measuring a resistance state of the magnetic memory element according to claim 8 obtained by flowing a current through the magnetic memory element in an out-of-plane direction.

17. A photonic spin register, comprising:
the magnetic memory element according to claim 1; and
a light irradiation unit configured to irradiate the antiferromagnetic layer with a pulse amplitude-modulated optical signal, wherein
in the antiferromagnetic layer, irradiation with the pulse amplitude-modulated optical signal allows reversal of the magnetic order of the antiferromagnet.

18. An apparatus, comprising:
the photonic spin register according to claim 17; and a unit connected to the photonic spin register inputting/outputting an optical signal from/to the photonic spin register.

19. An information processing system comprising at least one information processing apparatus which is provided with the photonic spin register according to claim 17, an input interface receiving an optical signal from the outside, a unit providing at least serial-parallel conversion by the photonic spin register, and an external interface outputting a signal to the outside.
